(19) United States
(12) Patent Application Publication
(10) Pub. No.: US 2020/0103480 A1
(43) Pub. Date: Apr. 2, 2020

(54) MAGNETIC RESONANCE FINGERPRINTING METHOD AND SYSTEM

(71) Applicant: Siemens Healthcare GmbH, Erlangen (DE)

(72) Inventors: Mathias Nittka, Baiersdorf (DE); Gregor Koerzdoerfer, Erlangen (DE); Peter Speier, Erlangen (DE); Jens Wetzl, Spardorf (DE)

(73) Assignee: Siemens Healthcare GmbH, Erlangen (DE)

(21) Appl. No.: 16/584,856

(22) Filed: Sep. 26, 2019

(30) Foreign Application Priority Data
Sep. 27, 2018 (EP) 18197267.0

(51) Int. Cl. G01R 33/48; G01R 33/56

(52) U.S. Cl. CPC G01R 33/4828; G01R 33/5608

(57) ABSTRACT

In a parameter value determination method, parameter values are determined based on at least two previously determined most similar comparison signal curves. As a result, the parameters for determining can be determined with a resolution greater than the resolution, underlying the comparison signal curves, of the values of the parameters to be determined. Advantageously, the determination of the parameter values are not limited to the values of the comparison signal curves, in other words, are not limited to the lattice/grid of the dictionary.

### CROSS REFERENCE TO RELATED APPLICATIONS

This patent application claims priority to European Patent Application No. 18197267.0, filed Sep. 27, 2018, which is incorporated herein by reference in its entirety.

### BACKGROUND

### Field

The disclosure relates to a magnetic resonance fingerprinting method for improved determination of local parameter values of an examination object.

### Related Art

The magnetic resonance technique (hereinafter the abbreviation MR stands for magnetic resonance) is a well-known technique with which images of the inside of an examination object can be generated. In simple terms, the examination object is positioned in a magnetic resonance device in a comparatively strong static, homogeneous base magnetic field, also called a B₀ field, having field strengths of 0.2 tesla to 7 tesla and more so its nuclear spins orient themselves along the base magnetic field. For triggering nuclear spin resonances, radio frequency excitation pulses (RF pulses) are irradiated into the examination object, the triggered nuclear spin resonances are measured as what is known as k-space data and MR images are reconstructed or spectroscopic data is determined on the basis thereof. For spatial coding of the measurement data, fast-switched magnetic gradient fields are superimposed on the base magnetic field, and these define the trajectories along which the measurement data is read out in the k-space. The recorded measurement data is digitized and stored as complex numerical values in a k-space matrix. From the k-space matrix filled with values, an associated MR image can be reconstructed, for example by means of a multi-dimensional Fourier transformation. A sequence, ordered in a particular manner, of RF pulses to be irradiated, gradients to be switched and readout operations is called a sequence.

Various sequence types are known which have different levels of sensitivity to parameters describing the substances contained in an examined examination object (for example the longitudinal longitudinal relaxation T1, the transverse relaxation T2 and the proton density). The MR images reconstructed from measurement data recorded with a particular sequence type show images of the examination object weighted according to the sensitivities of the sequence type used.

Magnetic resonance imaging by means of a magnetic resonance system can be used to determine a presence and/or a distribution of a substance which is found in an examination object. The substance can be, for example, a possibly pathological tissue of the examination object, a contrast agent, a marking substance or a metabolic product.

Information about the available substances can be obtained in a variety of ways from the recorded measurement data. A relatively simple source of information is, for example, image data reconstructed from the measurement data. However, there are also more complex methods which determine, for example from image point time series of image data reconstructed from successively measured measurement datasets, information about the examined examination object.

With the help of quantitative MR imaging techniques, absolute properties of the measured object can be determined, for example the tissue-specific T1 and T2 relaxation in humans. By contrast, the conventional sequences most commonly used in clinical routine only produce a relative signal intensity of different tissue types (what are known as weightings), so the diagnostic interpretation is largely subject to the radiologist's subjective assessment. Quantitative techniques therefore offer the obvious advantage of objective comparability but are hardly routinely used due to long measuring times.

More recent quantitative measurement methods, such as magnetic resonance fingerprinting (MRF) methods, could reduce the above-mentioned disadvantage of long measuring times to an acceptable level. In MRF methods, measurement data is successively recorded with different recording parameters. A series of image data is reconstructed from the successively recorded measurement data. A signal curve of one of the image points respectively of the series of image data is regarded as an image point time series. Here, the signal curve can be examined for all image data or at least for image points of the image data that are of interest. Such a signal curve of an image point time series is often referred to here as the “fingerprint” of the location of the examination object represented in the respective image point. Such a signal course can be used to determine the parameters present during the measurement in the location of the examination object represented by the image point.

For this purpose, these signal curves are compared by means of pattern recognition methods with signal curves of a pre-determined database of signal curves characteristic of particular substances (what is known as the “Dictionary”). Therefore, the substances represented in the image data reconstructed from the measurement data or the spatial distribution of tissue-specific parameters (such as the transverse relaxation T2, the effective transverse relaxation T2* or the longitudinal relaxation T1; what are referred to as T2, T2* and T1 maps) are determined in the represented examination object. The signal curves contained in such a dictionary can also have been created by simulations.

The principle of this method is therefore to compare measured signal curves with a large number of known signal curves. Signal curves for different combinations of T1 and T2 relaxation times as well as other parameters for the dictionary can have been determined. Reference is made to one “dimension” each of the dictionary for each of the parameters to be determined in which different parameter values of the respective parameter are included in order to provide different comparison values. The parameter values, for example T1 and T2 times, of an image point (pixel/voxel) in the image are then determined in particular by comparing the measured signal curve with all or part of the simulated signal curves. This method is called “Matching”. That signal curve of the dictionary, which is most similar to the measured signal curve, determines the parameters, for example relaxation parameters T1 and T2, of the respective image point in known MRF methods. In connection with MRF techniques, such determination of the parameter values is also referred to as the reconstruction or reconstruction process.

In principle, in addition to the already-mentioned tissue-specific parameters of an examined object, measurement-specific parameters, such as the field strengths of the applied magnetic fields or also the local distribution of the strength of an irradiated radiofrequency field B1+ can be determined since signals recorded by means of MR techniques can depend on the tissue-specific parameters present in an object being examined, as well as on measurement-specific parameters, which describe the conditions present during the measurement. The recording parameters used are chosen in such a way here that the recorded measurement data exhibits a dependency on the desired parameters to be determined. For example, sequence types can be used for the MRF method, which are sensitive to the desired parameters. Due to the dependencies and the variation of the recording parameters and their consideration in the comparison signal curves, the desired parameters can be determined from image point time series recorded in this way.

For MRF methods, basically any echo technique (in particular spin echo (SE) techniques and gradient echo (GRE) techniques) in combination with any method for k-space sampling (for example Cartesian, spiral, radial) can be used.

An MRF method, which considers the tissue-specific parameters T1 and T2 in the dictionary used and determines them in measured image point time series, is described, for example, in the article by Ma et al., “Magnetic Resonance Fingerprinting”, Nature, 495: p. 187-192 (2013). There, a TrueFISP-based (“true fast imaging with steady-state free precession”) sequence is used in combination with spiral k-space sampling.

Another MRF implementation is described by Jiang et al. in the article “MR Fingerprinting Using Fast Imaging with Steady State Precession (FISP) with Spiral Readout”, Magnetic Resonance in Medicine 74: p. 1621-1631, 2015. There, a FISP sequence (“Fast Imaging with Steady State Precession”) is used in combination with spiral sampling. After an adiabatic 180° RF inversion pulse for targeted interference of the state of equilibrium of the spins, a sequence of RF excitation pulses with pseudorandomized flip angles is applied and each echo resulting after one of the RF excitation pulses respectively is read out with a single spiral k-space trajectory. n RF excitation pulses are used, which generate as many echoes. A single image is reconstructed from the measurement data of each echo recorded along the respective k-space trajectory. A signal curve is extracted from the n single images for each image point, and this is compared with the simulated curves. The time interval TR between two successive RF excitation pulses of the n RF excitation pulses can likewise be varied here, for example pseudorandomized.

An important aspect of MRF techniques which distinguishes them from other quantitative MR methods is the determination of said dictionary. As already mentioned, the dictionary is often created by various possible comparison signal curves being precalculated, for example by simulation, in particular on the basis of the Bloch equations. In contrast thereto, in other quantitative methods for the determination of parameter values by means of MR, the measured signals are usually fitted to a model. A simulation of signal curves intended to form an MRF dictionary only needs to be carried out once and, as in the case of other quantitative methods, a new fit does not need to be carried out with each measurement. As a result, significantly more complex signal models can be used and yet the reconstruction times are kept short.

As the complexity of the simulation of comparison signal curves (for example with respect to the number of incorporated parameters and/or with respect to the resolution of the possible values of the parameters) increases, however, the time required for simulation of a dictionary increases.

The same applies to the reconstruction, since the time required for matching also increases with the number of comparison signal curves contained in a dictionary.

Methods are already known in which the dictionary used is prepared and distributed among different subgroups, and then in a first step firstly the least similar subgroups are sorted out to thus reduce the number of comparisons that are required for matching in a second step. A method of this kind is exemplified in the article by Cauley S et al, “Fast group matching for MR fingerprinting reconstruction”, Magnetic Resonance in Medicine 74:523-528, 2015. Another way to keep the effort involved in the reconstruction down is to use an “approximate nearest neighbor” search at times of measured MRF signal curves with corresponding times of the comparison signal curves included in the dictionary and using the results of this comparison it will be decided what time should be compared next. An approach of this kind is described, for example, in the article by Cline C et al, “AIR-MRF: Accelerated iterative reconstruction for magnetic resonance fingerprinting”, Magnetic Resonance Imaging 41:29-40, 2017.

Furthermore, there are already ideas that try to use completely different similarity measurements instead of matching, which it is hoped can be carried out more quickly. A method of this kind is described, for example in the article by Hoppe E. et al, “Deep Learning for Magnetic Resonance Fingerprinting: A New Approach for Predicting Quantitative Parameter Values from Time Series”, Studies in Health Technology and Informatics 243:202-206, 2017.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a flowchart of a method according to an exemplary embodiment of the disclosure.

FIG. 2 is a diagram of a determination of parameter values based on already-determined most similar comparison signal curves according to an exemplary embodiment of the disclosure.

FIG. 3 is a magnetic resonance system according to an exemplary embodiment of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure.

An object of the present disclosure is to reduce the time required for an MRF reconstruction process without reducing its quality.

In an exemplary embodiment of the present disclosure, a method for the determination of parameter values in image points of an examination object by a magnetic resonance fingerprinting (MRF) technique includes:
loading a number N of comparison signal curves (D), which are each assigned to the specified values of the parameters to be determined,
acquiring at least one image point time series (BZS) of the examination object using an MRF recording method comparable to the loaded comparison signal curves,
performing a signal comparison (105) of at least one section of the respective signal curve of the acquired image point time series (BZS) with a corresponding section of the loaded comparison signal curves (D) for the determination of similarity values (V) of the acquired image point time series (BZS) with the loaded comparison signal curves (D),
determining a second number n, where 2≤n (≤N), of the most similar comparison signal curves (d) of the loaded comparison signal curves (D) with the n highest determined similarity values (V),
determining the values (P) of the parameters to be determined on the basis of the n determined most similar comparison signal curves (d),
saving and/or outputting the values (P), determined for the respective image point, of the parameters to be determined.

By way of the inventive determination of parameter values, not as previously by 1:1 assignment with a comparison signal curve, but on the basis of at least two previously determined most similar comparison signal curves, the parameters for determining can be determined with a resolution greater than the resolution, underlying the comparison signal curves, of the values of the parameters to be determined. Therefore, the values possible as a result of the determination of the parameter values by way of the inventive method are not limited to the values of the comparison signal curves, in other words are not limited to the lattice/grid of the dictionaries.

As a result, either the effort to be made in the acquisition of the comparison signal curves can be kept low without affecting the accuracy of the ultimately determined parameter values, whereby, in particular, the time required for creation, for example simulation, of an MRF dictionary and for the MRF reconstruction process can be reduced without significant losses in quality. Or the accuracy of the determination of the values of the parameters to be determined can be increased without the need for further comparison signal curves. Overall, therefore, the computational effort as well as the time required can already be kept low in the acquisition of the comparison signal curves in relation to the achievable accuracy of the reconstructed parameter values, or can even be reduced, for example because fewer comparison signal curves have to be simulated or measured in order to achieve a desired resolution of the parameter values. It is also possible therefore to reduce the computational effort and time required for the reconstruction of the parameter values, for example because fewer comparison operations have to be carried out with the same accuracy of determination of the parameter values.

If a smaller number of comparison signal curves, in other words a smaller dictionary with a coarsely resolved grid, is sufficient for the desired determination of the values of the parameters, the memory requirement for the dictionary is also reduced.

Here, the second number n can be chosen to be greater than the number of different parameters to be determined in order to create more freedom in the parameter values possible as a result of determination.

In an exemplary embodiment, the second number n can be chosen to be one greater than the number of different parameters to be determined. Therefore, the computational effort can be kept low and at the same time a much higher level of accuracy on determination of the parameter values can be achieved than with a previously customary 1:1 assignment of a recorded image point time series to a comparison signal curve.

A similarity value of an acquired image point time series with one of the loaded comparison signal curves is a measure of matching of the acquired point time series with the considered comparison signal curve. Similarity values of this kind are used in the context of MRF matching to determine the comparison signal curve that most matches an acquired image point time series, and therefore which bears the greatest similarity, in other words the highest similarity value. In principle all similarity measures also known for vectors can be used as a measure of this kind.

The determination of a similarity value of an acquired image point time series with one of the loaded comparison signal curves can include a calculation of the inner product of the image point time series and the loaded comparison signal curve. The inner product, also known as the scalar product, is an easy-to-calculate quantity which provides a scalar value which is sufficiently well suited as a similarity value.

The determination of the values of the parameters to be determined on the basis of the n determined most similar comparison signal curves can include an averaging. An averaging is easy to calculate and provides the central tendency of a distribution, and therefore a good approximation of the values sought. For averaging, in principle, any type of averaging therefore, for example, a formation of the arithmetic mean, of the geometric mean (n^{th} root from the product of the n considered values), of the root mean square (RMS) or a median, can be determined. The type of averaging chosen can depend on which central tendency is to be represented.

The determination of the values of the parameters to be determined on the basis of the n determined most similar comparison signal curves can include a weighting. The determination of the values of the parameters to be determined can be influenced by weighting, for example according to other known circumstances or conditions.

The weighting can be determined on the basis of the determined similarity values. Therefore, the result of the determination of the values of the parameters to be determined can be closer to those values assigned to the comparison signal curves, which have a higher similarity value.

It is conceivable that the loaded comparison signal curves are a subset of a larger number of existing comparison signal curves. A determination of such a subgroup can be made, for example, as described in the above-mentioned article by Cauley et al.

The loaded comparison signal curves can also be compressed comparison signal curves. A compression of this kind is described for example in the article by McGivney et al., “SVD Compression for Magnetic Resonance Fingerprinting in the Time Domain”, IEEE Trans. Med. Imaging 33: 2311-22, 2014.

A magnetic resonance system according to an exemplary embodiment includes a magnetic unit, a gradient unit, a radio frequency unit and a control device with a parameter value determiner designed for carrying out an inventive method according to one or more aspects of the disclosure.

A computer program according to an exemplary embodiment implements an inventive method on a control device when it is run on the control device.

The computer program can also be in the form of a computer program product, which can be loaded directly into a memory of a control device, having program code means to carry out an inventive method when the computer program product is run in the processor of the computing system.

An inventive electronically readable data carrier includes electronically readable control information stored thereon, which includes at least one inventive computer program and is configured in such a way that it carries out an inventive method when the data carrier is used in a control device of a magnetic resonance system.

The advantages and designs disclosed in relation to the method also apply analogously to the magnetic resonance system, the computer program and the electronically readable data carrier.

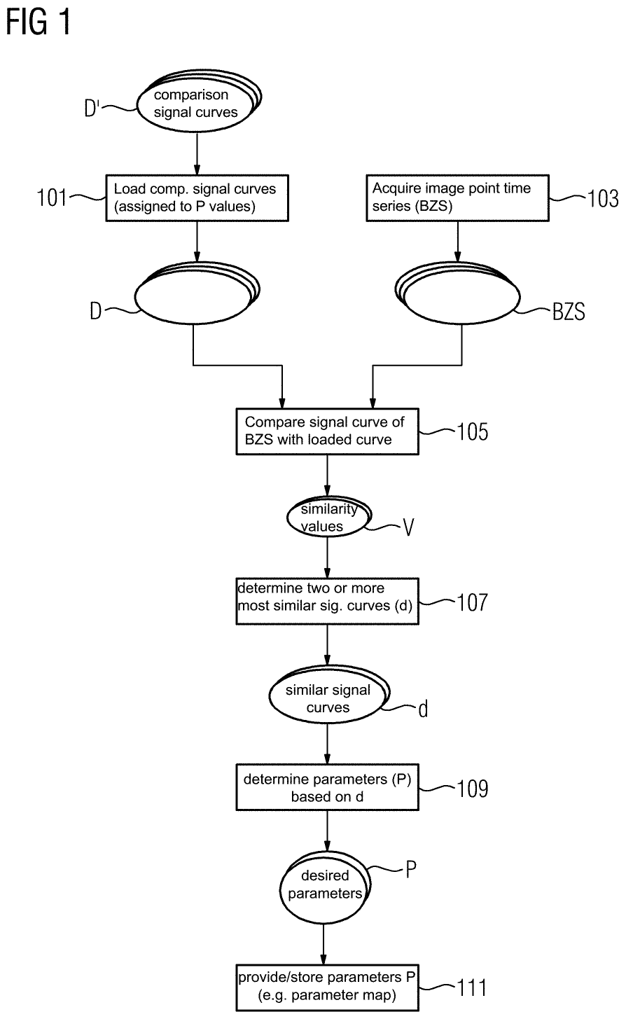

FIG. 1 is a schematic flowchart of a method for determining parameter values in image points of an examination object by means of a magnetic resonance fingerprinting (MRF) technique.

In an exemplary embodiment, a number N of comparison signal curves D is loaded, which are in each case assigned to predetermined values of the parameters to be determined (block 101). The N loaded comparison signal curves D have been created in such a way that desired parameters, for example at least one tissue-specific or measurement-specific parameter, for example, at least one of the parameters including the transverse relaxation, the longitudinal relaxation, the proton density, the susceptibility, the magnetization transfer, the field strength of the applied magnetic fields or the field strength of the applied radio frequency fields, can be determined.

The loaded N comparison signal curves D can have been created as a dictionary by simulation or measurement of signal curves for a grid at certain values of the desired parameters to be determined, with the grid specifying a resolution of the respective parameter values.

In an exemplary embodiment, comparison signal curves D′ are first created, and the loaded comparison signal curves D are a subset of these existing comparison signal curves D′. In an exemplary embodiment, a method in accordance with the method described in the above-mentioned article by Cauley et al can be used for the selection of the subgroup.

In an exemplary embodiment, the N loaded comparison signal curves D can also be compressed comparison signal curves, which were obtained by a compression of created comparison signal curves D′. One possible type of compression is described in the above-mentioned article by McGivney et al.

From an examination object, for example a patient, positioned in a magnetic resonance system, at least one image point time series BZS is acquired with the aid of an MRF recording method (block 103). In this connection, image point time series are recorded, as is customary with MRF methods, in a way that allows acquired image point time series to be compared with loaded comparison signal curves of a dictionary.

In an exemplary embodiment, a signal comparison of at least one section of the respective signal curve of the acquired image point time series BZS with a corresponding section of the loaded comparison signal curves D is carried out to determine similarity values V of the acquired image point time series BZS with the loaded comparison signal curves D (block 105).

A determination of a similarity value V of an acquired image point time series BZS with one of the loaded comparison signal curves D can include, for example, calculation of the inner product of the image point time series BZS and the loaded signal comparison curve D. In an exemplary embodiment, the similarity value V of an acquired image point time series BZS with one of the loaded comparison signal curves D can be the inner product of the acquired image point time series BZS with the considered loaded comparison signal curve.

In an exemplary embodiment, based on the determined similarity values V, a second number n of at least two most similar comparison signal curves d of the loaded comparison signal curves D is determined in such a way that the most similar comparison signal curves d have the n best determined similarity values V (block 107).

In an exemplary embodiment, if the second number n is greater than the number of different parameters to be determined, the sought parameter value can then be determined with a higher degree of freedom.

In order to keep the second number n low, and to thus reduce the computational effort, the second number n can be chosen to be one greater than the number of different parameters to be determined.

In an exemplary embodiment, the values P of the desired parameters to be determined are determined (block 109) on the basis of the n determined most similar comparison signal curves d. In an exemplary embodiment, the parameter values assigned to the n determined most similar comparison signal curves are used for the determination of the values P of the parameters to be determined of the image point of the image point time series BZS.

In an exemplary embodiment, the determination of the values P of the parameters to be determined on the basis of the n determined most similar comparison signal curves d can include an averaging. Therefore, a value P of a parameter to be determined can be determined, for example, by an averaging of the values corresponding to the n determined most similar comparison signal curves.

In an exemplary embodiment, the determination of the values P of the parameters to be determined on the basis of the n determined most similar comparison signal curves d can additionally or alternatively include a weighting. This can potentially influence the result of the determination of the parameter value, for example an expected reliability of the individual values.

In an exemplary embodiment, the weighting is determined based on the determined similarity values V, whereby a result of the determination of a parameter value is closer to those values of the n determined most similar comparison signals d, which have a greater match and therefore a greater similarity.

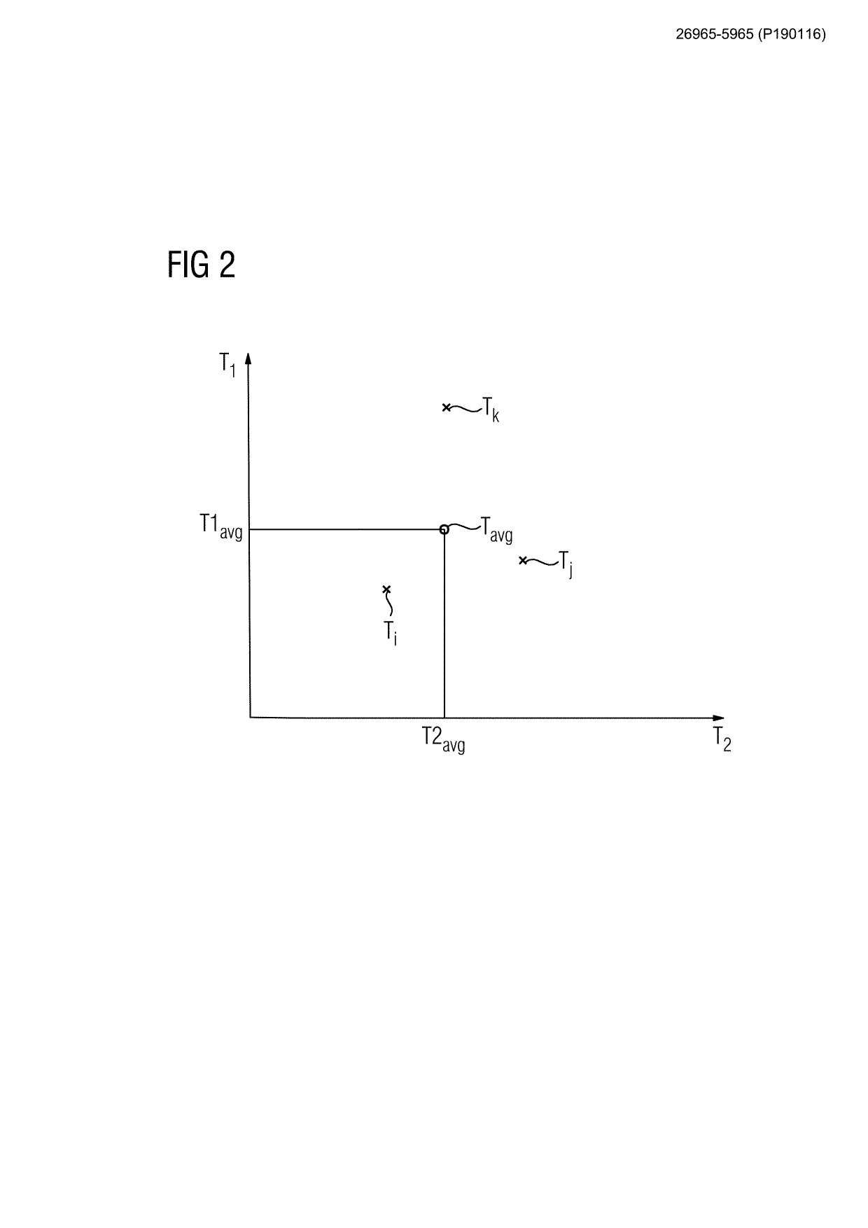

FIG. 2 illustrates a determination of parameter values, according to an exemplary embodiment, on the basis of already-determined most similar comparison signal curves using the simple example of a determination of the values of here two parameters T1 and T2. As already mentioned above, the two parameters can be, for example, the transverse relaxation T2 and the longitudinal relaxation T1. However, any other parameters that can be simultaneously determined by means of MRF techniques can be determined.

In the example shown, the three most similar comparison signal curves d₁, d₂, d₃ with the highest similarity values V₁, V₂ and V₃ are determined for an image point time series BZS. The similarity V was determined, for example, by formation of the inner product V₁=<BZS,d₁>, V₂=<BZS,d₂> and V₃=<BZS,d₃>.

The parameter values tuples Tᵢ, Tⱼ and Tₖ associated with the most similar comparison signal curves d₁, d₂, d₃, and which each represent a pair of values T₁-T₂ of the considered parameters, are located in FIG. 2 at the places marked by crosses in the stretched T₁-T₂ coordinate system and are therefore the n (here n=3) best value tuples.

The result of the determination of the values of the parameters T₁ and T₂ can then be determined, for example, as represented from the mean, for example the arithmetic mean, the value tuples Tᵢ, Tⱼ and Tₖ as a result tuple T_{avg}.

As already mentioned, by using additional weighting factors, the similarity (defined by the inner product p) can be taken into account in the averaging. For example, T_{avg} could be determined as T_{avg}=mean (<V_{1,2,3}, T_{i,j,k}>). Therefore, the result T_{avg} would be closer to the values with a greater match with the comparison signal curves d1, d2, d3 of the dictionary.

By way of the inventive method, the size of the dictionary can be reduced since the results are no longer reduced to the grid of the dictionary. The time required for the simulation and reconstruction process can be significantly reduced therefore.

By way of the inventive method, parameter values can be determined with a resolution higher than the resolution of the grid used when creating the dictionary for the comparison signal curves.

The values P, determined for the respective image point, of the parameters to be determined can be stored, for example, in the form of a parameter map, and/or output, for example also on an input/output device I/O of a magnetic resonance system or on another display (block 111).

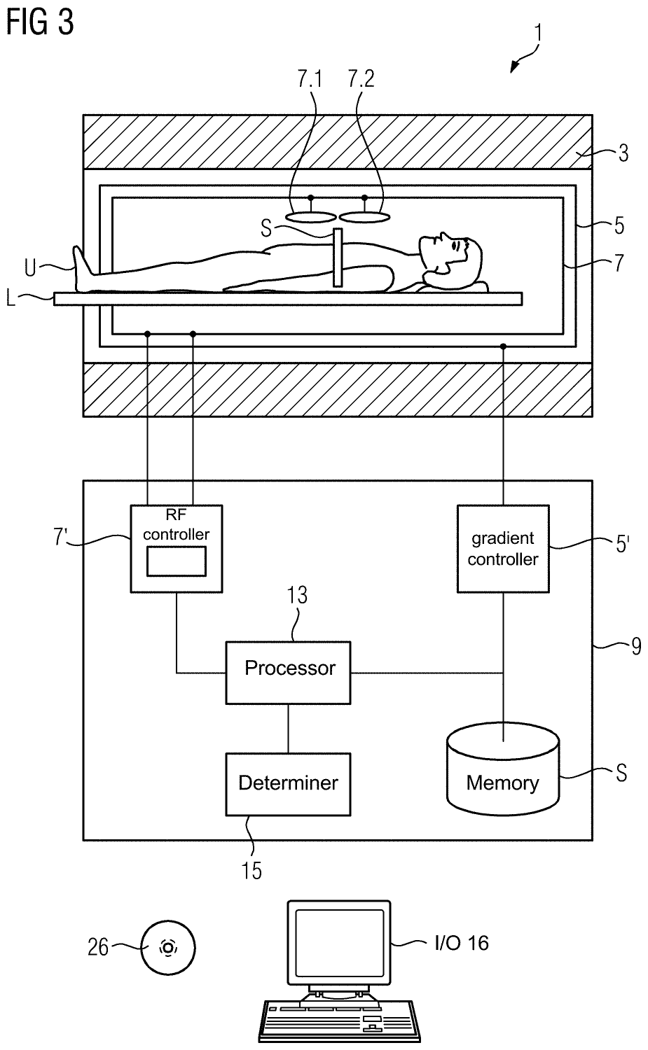

FIG. 3 schematically illustrates a magnetic resonance (MR) system 1. In an exemplary embodiment, the MR system 1 includes a magnetic unit 3 configured to generate the base magnetic field, a gradient unit 5 configured to generate the gradient fields, a radio frequency (RF) unit 7 configured to irradiate and receive radio frequency (RF) signals and a control device/facility 9 configured to perform the method according to one or more aspects described herein. In an exemplary embodiment, the control device 9 can be referred to as controller 9 or main controller 9.

In FIG. 3, these units of the magnetic resonance system 1 are schematically represented. In an exemplary embodiment, the radio frequency unit 7 includes a plurality of subunits, for example, a plurality of coils such as the schematically shown coils 7.1 and 7.2 or more coils, which can be configured either only for transmitting radio frequency signals or only for receiving triggered radio frequency signals or for both.

For the examination of an examination object U, for example, of a patient or also of a phantom, the latter can be introduced on a couch L into the magnetic resonance system 1 in its measuring volume. Slice S is an example of the target volume of the examination object from which measurement data is to be recorded.

In an exemplary embodiment, the control device 9 is configured to control the magnetic resonance system 1, including controlling the gradient unit 5 by a gradient controller 5′ and the radio frequency unit 7 by a radio frequency transceiving controller 7′. The radio frequency unit 7 can include a plurality of channels on which signals can be transmitted or received. In an exemplary embodiment, the control device 9 (and/or one or more of its components) includes processor circuitry that is configured to perform one or more operations and/or functions of the control device 9, including controlling the magnetic resonance system 1 to obtain scan data and/or controlling the operations of one or more components of the control device 9.

In an exemplary embodiment, the radio frequency unit 7 together with its radio frequency transceiving controller 7′ is responsible for the generation and irradiation (transmission) of a radio frequency exchange field for the manipulation of the spins in a region for manipulation (for example, in slices S to be measured) of the examination object U. The center frequency of the radio frequency exchange field, also referred to as the B 1 field, is usually set as far as possible so it is close to the resonance frequency of the spins to be manipulated. Deviations from the center frequency of the resonance frequency are called off-resonance. Currents controlled by means of the radio frequency transceiving controller 7′ are applied to the RF coils for the generation of the B 1 field in the radio frequency unit 7. In an exemplary embodiment, the RF controller 7′ includes processor circuitry that is configured to control currents applied to the RF-coils in the RF unit 7.

In an exemplary embodiment, the control device 9 includes a parameter determiner 15 with which inventive signal comparisons can be carried out for the determination of parameter values.

The control device 9 is designed overall to carry out an inventive method. In an exemplary embodiment, the determiner 15 includes processor circuitry that is configured to perform signal comparisons to determine parameter values.

A processor 13 encompassed by the control device 9 is designed to perform all the necessary calculation operations for the necessary measurements and determinations.

Intermediate results and results required or determined in the process for this can be stored in a memory storage unit S of the control device 9. The memory storage unit S is any well-known volatile and/or non-volatile memory. The units shown should not necessarily be taken to mean physically separate units, but merely represent a breakdown into units of meaning, which, however, can also be implemented, for example, in fewer units or even in just a single physical unit. In an exemplary embodiment, the processor 13 includes processor circuitry that is configured to perform one or more computing operations required for the necessary scans and determinations Control commands can be routed via an input/output (I/O) device 16 of the magnetic resonance system 1, for example by a user, to the magnetic resonance system and/or results of the control device 9, such as image data, can be displayed. In an exemplary embodiment, the I/O device 16 is a computer, mobile communication device (e.g. smartphone, tablet), or another stationary or mobile computing device as would be understood by one of ordinary skill in the relevant arts.

In an exemplary embodiment, a method described herein can also be in the form of a computer program product, which includes a program and implements the described method on a control device 9 when it is run on the control device 9. Similarly, an electronically readable memory storage medium 26 can be present, having electronically readable control information stored thereon, which includes at least one such computer program product described above and is configured in such a way that it carries out the described method when the memory storage medium 26 is used in a control device 9 of a magnetic resonance system 1. In exemplary embodiment, the memory storage medium 26 is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM).

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general purpose computer.

For the purposes of this discussion, the term “processor circuitry” shall be understood to be circuit(s), processor(s), logic, or a combination thereof. A circuit includes an analog circuit, a digital circuit, state machine logic, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM).

The memory can be non-removable, removable, or a combination of both.

1. A method for determining parameter values in image points of an examination object using a magnetic resonance fingerprinting (MRF) technique, comprising:
loading comparison signal curves, each being assigned to specified parameter values to be determined;
acquiring, using a magnetic resonance (MR) scanner, at least one image point time series of the examination object using an MRF recording method comparable to the loaded comparison signal curves;
performing a signal comparison of at least one section of the respective signal curve of the acquired at least one image point time series with a corresponding section of the loaded comparison signal curves to determine similarity values of the acquired image point time series with the loaded comparison signal curves;
determining two or more largest similarity values, of the determined similarity values, to determine two or more most similar comparison signal curves of the loaded comparison signal curves;
determining the parameter values based on the determined two or more most similar comparison signal curves; and
providing, as an output of the MR scanner, an electronic signal representing the determined parameter values for the respective image points of the examination object.

2. The method as claimed in claim 1, wherein a number of the two or more most similar comparison signal curves is greater than a number of different parameters values to be determined.

3. The method as claimed in claim 2, wherein the number of the two or more most similar comparison signal curves is greater by one than the number of different parameters values to be determined.

4. The method as claimed in claim 1, wherein the determination of each of the similarity values, comprises calculating an inner product of the at least one image point time series and one of the loaded comparison signal curves.

5. The method as claimed in claim 1, wherein the determination of the parameter values comprises averaging the two or more most similar comparison signal curves, the parameter values being determined based on the average of the determined two or more most similar comparison signal curves.

6. The method as claimed in claim 1, wherein the determination of the parameter values comprises weighting the parameter values.

7. The method as claimed in claim 6, wherein the weighting is determined based on the determined similarity values.

8. The method as claimed in claim 1, wherein the loaded comparison signal curves are a subgroup of existing comparison signal curves.

9. The method as claimed in claim 1, wherein the loaded comparison signal curves are compressed comparison signal curves.

10. A computer program product having a computer program which is directly loadable into a memory of a controller of the MR scanner, when executed by the controller, causes the magnetic resonance system to perform the method of claim 1.

11. A non-transitory computer-readable storage medium with an executable computer program stored thereon, that when executed, instructs a processor to perform the method of claim 1.

12. A magnetic resonance (MR) system comprising:
a MR scanner configured to perform a magnetic resonance fingerprinting (MRF) method to acquire at least one image point time series of the examination object; and
a controller that is configured to:
load comparison signal curves, each being assigned to specified parameter values to be determined;
perform a signal comparison of at least one section of a respective signal curve of the acquired at least one image point time series with a corresponding section of the loaded comparison signal curves to determine similarity values of the acquired image point time series with the loaded comparison signal curves;
determine two or more largest similarity values, of the determined similarity values, to determine two or more most similar comparison signal curves of the loaded comparison signal curves;
determine the parameter values based on the determined two or more most similar comparison signal curves; and
provide, as an output, an electronic signal representing the determined parameter values for the respective image points of the examination object.

13. The MR system as claimed in claim 12, wherein a number of the two or more most similar comparison signal curves is greater than a number of different parameters values to be determined.

14. The MR system as claimed in claim 13, wherein the number of the two or more most similar comparison signal curves is greater by one than the number of different parameters values to be determined.

15. The MR system as claimed in claim 12, wherein the determination of each of the similarity values, comprises calculating an inner product of the at least one image point time series and one of the loaded comparison signal curves.

16. The MR system as claimed in claim 12, wherein the determination of the parameter values comprises averaging the two or more most similar comparison signal curves, the parameter values being determined based on the average of the determined two or more most similar comparison signal curves.

17. The MR system as claimed in claim 12, wherein the determination of the parameter values comprises weighting the parameter values.

18. The MR system as claimed in claim 17, wherein the weighting is determined based on the determined similarity values.

19. The MR system as claimed in claim 12, wherein the loaded comparison signal curves are a subgroup of existing comparison signal curves.

20. The MR system as claimed in claim 12, wherein the loaded comparison signal curves are compressed comparison signal curves.
